(19) United States
(12) Patent Application Publication
(10) Pub. No.: US 2026/0333845 A1
(43) Pub. Date: Oct. 22, 2026

(54) SEMICONDUCTOR INTEGRATED CIRCUIT

(71) Applicant: ROHM Co., LTD., Kyoto (JP)

(72) Inventors: Tadayuki Sakamoto, Kyoto (JP); Kenichi Motoki, Kyoto (JP)

(21) Appl. No.: 19/577,005

(22) Filed: Mar. 24, 2026

(30) Foreign Application Priority Data
Apr. 2, 2025 (JP) 2025-061367

(51) Int. Cl. H10D 84/00; H10D 1/43

(52) U.S. Cl. CPC H10D 84/209; H10D 1/43

(57) ABSTRACT

Provided is a semiconductor integrated circuit including a semiconductor substrate and a resistive voltage divider circuit that includes an input node, a ground node, an output node, and “n” (n≥3) poly resistors connected in series between the input node and the ground node and having the same size. One of the “n” poly resistors closest to the ground node and one thereof closest to the input node are referred to as a first poly resistor and an n-th poly resistor, respectively. The output node is connected to a connection node between an m-th poly resistor and an (m+1)-th poly resistor. The first to m-th poly resistors are formed on a first well. The first well is connected to the ground node. The (m+1)-th to n-th poly resistors are formed on a second well. The second well is connected to a node closest to a center of the “n” poly resistors.

### PRIORITY

The present disclosure contains subject matter related to that disclosed in Japanese Priority Patent Application JP 2025-061367 filed in the Japan Patent Office on Apr. 2, 2025, the entire content of which is hereby incorporated by reference.

### BACKGROUND

The present disclosure relates to a resistor formed in a semiconductor integrated circuit.

One of important components of a semiconductor integrated circuit is a resistor. There are various types of resistors, and a poly resistor, a diffused resistor, a metal resistor, and other resistors are used according to applications thereof.

A resistance value of a resistor formed on a semiconductor substrate changes slightly according to a voltage applied thereto. This is referred to as voltage modulation. The voltage modulation is on the order of 0.1% or lower at most even when a high voltage exceeding 10 V is applied, and hence, the voltage modulation does not pose a problem in many applications.

An example of the related art is disclosed in Japanese Patent Laid-open No. 2025-7777.

When a resistor to be influenced by the voltage modulation is used to form a resistive voltage divider circuit, it is not possible to achieve a voltage division ratio being a design value.

### BRIEF DESCRIPTION OF THE DRAWINGS

FIG. 1 is a drawing for illustrating a cross-sectional view of a poly resistor and circuit symbols;

FIG. 2 is a graph for illustrating influence of voltage modulation of the poly resistor;

FIG. 3 is a diagram for illustrating a semiconductor integrated circuit including a resistive voltage divider circuit;

FIG. 4 is a circuit diagram of a semiconductor integrated circuit according to comparative technique 1;

FIG. 5 is a circuit diagram of a semiconductor integrated circuit according to comparative technique 2;

FIG. 6 is a circuit diagram of a resistive voltage divider circuit according to a first embodiment;

FIG. 7 is a circuit diagram of a resistive voltage divider circuit according to modification example 1;

FIG. 8 is a circuit diagram of a resistive voltage divider circuit according to a second embodiment; and

FIG. 9 is a circuit diagram of a resistive voltage divider circuit according to modification example 2.

### DETAILED DESCRIPTION

### Overview of Embodiments

A description is now given of an overview of some exemplary embodiments of the present disclosure. This overview simplifies and describes some concepts of one or more embodiments as an introduction to a detailed description given later for the purpose of basic understanding of the embodiments, and is not intended to limit the breadth of the disclosure. This overview is not a comprehensive overview of all conceivable embodiments, and it is intended to neither identify important elements of all embodiments nor delineate scopes of some or all aspects. For the sake of convenience, “one embodiment” may be used to refer to one embodiment (an example or a modification example) or a plurality of embodiments (examples or modifications) disclosed in this specification.

A semiconductor integrated circuit according to one embodiment includes a semiconductor substrate and a resistive voltage divider circuit that is formed on the semiconductor substrate and divides an input voltage. The resistive voltage divider circuit includes an input node which receives an input voltage, a ground node, an output node, and “n” (n≥3) poly resistors which are connected in series between the input node and the ground node and have the same size. One of the “n” poly resistors closest to the ground node is referred to as a first poly resistor, and one of the “n” poly resistors closest to the input node is referred to as an n-th poly resistor. The output node is connected to a connection node between an m-th poly resistor and an (m+1)-th poly resistor. The first to m-th poly resistors are formed on a first well, and the first well is connected to the ground node. The (m+1)-th to n-th poly resistors are formed on a second well, and the second well is connected to a node closest to the center of the “n” poly resistors.

The “node closest to the center of the “n” poly resistors” is a node at which electric potential closest to a midpoint voltage between the input voltage and a ground voltage is generated. With this configuration, line-symmetrical voltage modulation with respect to the node connected to the second well is applied to resistance values of the (m+1)-th to n-th poly resistors. Variations in the resistance values of the poly resistors that are present at symmetrical positions cancel each other out, and hence, a resistance value of an upper resistor formed of the (m+1)-th to n-th poly resistors is hardly influenced by the voltage modulation. As a result, an ideal resistance voltage division ratio can be obtained.

When each of the poly resistors is formed on an independent well, a space is required between the wells, and hence, a circuit area is increased. However, with the configuration described above, the number of wells is two, the number of spaces between the wells is one, and hence, the circuit area can be reduced.

A semiconductor integrated circuit according to one embodiment includes a semiconductor substrate and a resistive voltage divider circuit that is formed on the semiconductor substrate and divides an input voltage. The resistive voltage divider circuit includes an input node which receives an input voltage, a ground node, an output node, and “n” (n≥3) poly resistors which are connected in series between the input node and the ground node and have the same size. One of the “n” poly resistors closest to the ground node is referred to as a first poly resistor, and one of the “n” poly resistors closest to the input node is referred to as an n-th poly resistor. The output node is connected to a connection node between an m-th poly resistor and an (m+1)-th poly resistor. When “k” is an integer closest to n/2, the first poly resistor to a k-th poly resistor are formed on the first well, the first well is connected to the ground node, a (k+1)-th poly resistor to the n-th poly resistor are formed on a second well, and the second well is connected to the input node.

With this configuration, the voltage modulation applied to the poly resistors formed on the first well and the voltage modulation applied to the poly resistors formed on the second well are opposite to each other in direction, and hence, variations in the resistance values of the poly resistors formed on the first well and variations in the resistance values of the poly resistors formed on the second well cancel each other out. As a result, an ideal resistance voltage division ratio can be obtained.

Moreover, when each of the poly resistors is formed on an independent well, a space is required between the wells, and hence, a circuit area is increased. However, with the configuration described above, the number of wells is two, the number of spaces between the wells is one, and hence, the circuit area can be reduced.

In one embodiment, m/n may be ⅛ or smaller. As the voltage division ratio m/n becomes smaller, an effect of suppressing the influence of the voltage modulation is exerted more.

In one embodiment, “m” may be 1.

### Embodiments

A description is now given of preferred embodiments with reference to the drawings. It is assumed that the same reference sign is assigned to equivalent or the same components, members, and pieces of processing illustrated in each drawing, and a redundant description thereof is appropriately omitted. Moreover, the embodiments do not limit the present disclosure and are examples, and all features and combinations thereof described in the embodiments are not necessarily the essence of the present disclosure.

In this specification, a “state in which a member A is connected to a member B” includes a case in which the member A and the member B are physically directly connected to each other and a case in which the member A and the member B are indirectly connected to each other via another member that does not substantially affect an electrical connection state therebetween or does not impair functions and effects achieved by coupling therebetween.

Similarly, a “state in which a member C is provided between a member A and a member B” includes a case in which the member A and the member C or the member B and the member C are directly connected to each other and a case in which the member A and the member C or the member B and the member C are indirectly connected to each other via another member that does not substantially affect an electrical connection state therebetween or does not impair functions and effects achieved by coupling therebetween.

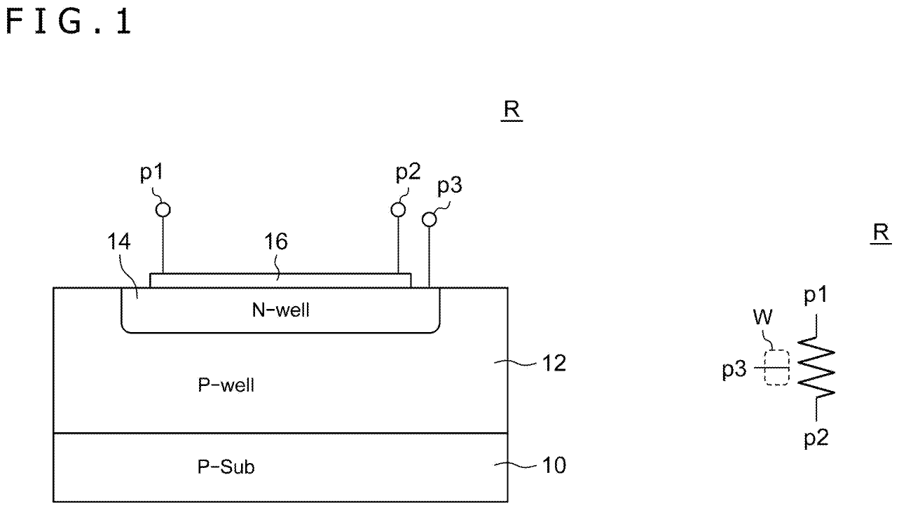

FIG. 1 is a drawing for illustrating a cross-sectional view of a poly resistor and circuit symbols. A poly resistor R is formed on a semiconductor substrate 10. A P-type well 12 is formed on the semiconductor substrate 10. An N-type well 14 is formed in the P-type well 12. A polysilicon region 16 is formed on the N-type well 14. Both of ends of the polysilicon region 16 form terminals P1 and P2 of the poly resistor R. Moreover, to a terminal P3 pulled out from the N-type well 14, any voltage can be applied.

As illustrated on the right side of FIG. 1, the poly resistor R is represented as a three-terminal element including P1, P2, and P3 in this specification.

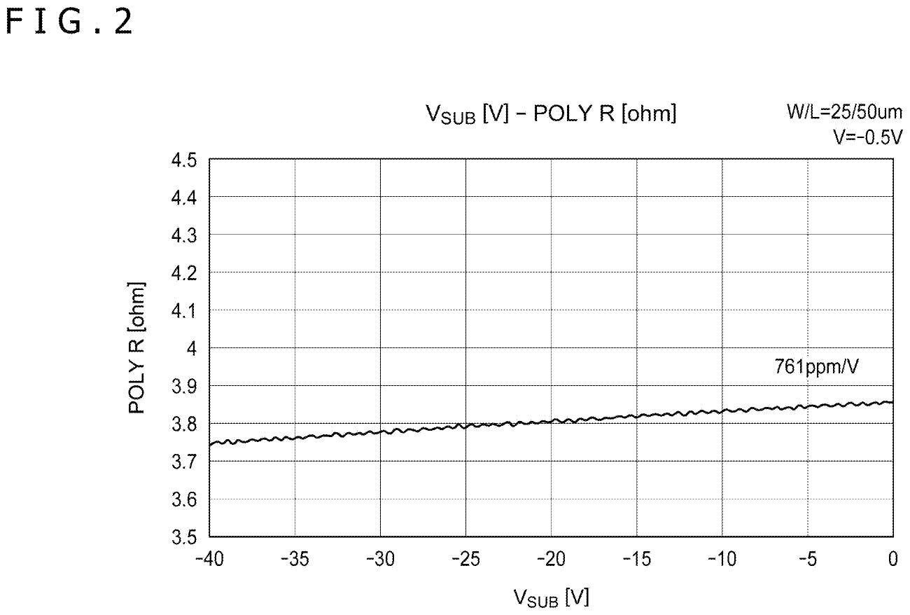

FIG. 2 is a graph for illustrating influence of voltage modulation of the poly resistor. A horizontal axis indicates a substrate voltage Vsub, and a vertical axis indicates a resistance value. A width W of the poly resistor is set to 25 μm, and a length L thereof is set to 50 μm. The resistance value changes at a gradient of 761 ppm/V with respect to the substrate voltage Vsub.

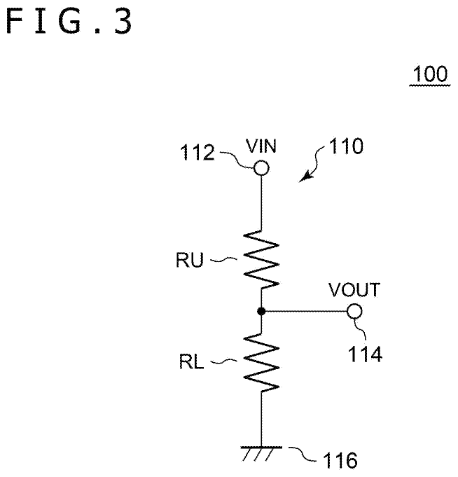

FIG. 3 is a diagram for illustrating a semiconductor integrated circuit 100 including a resistive voltage divider circuit 110.

The resistive voltage divider circuit 110 divides an input voltage VIN of an input node 112, and outputs an output voltage Vout from an output node 114. An upper resistor RU is connected between the input node 112 and the output node 114, and a lower resistor RL is connected between the output node 114 and a ground node 116.

A voltage division ratio of this resistive voltage divider circuit 110 is RL/(RL+RU), and hence, Vout is given as follows.

Vout=RL/(RL+RU)×VIN

The upper resistor RU and the lower resistor RL are each formed of the poly resistors R of FIG. 1 on the semiconductor substrate.

Before a description of configurations of the resistive voltage divider circuits 110 according to the embodiments, a description is now given of configurations of resistive voltage divider circuits according to comparative techniques and problems thereof. Here, the description is given of, as an example, resistive voltage divider circuits having a voltage division ratio of 1/16.

### (Comparative Technique 1)

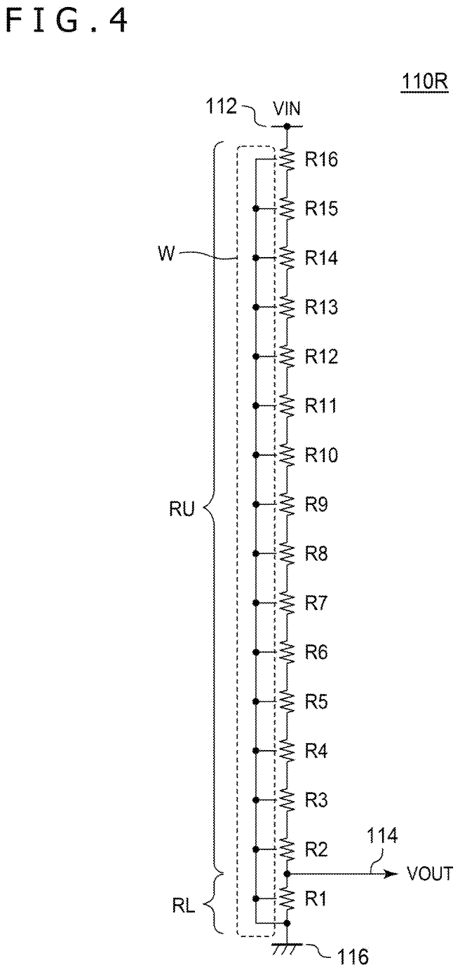

FIG. 4 is a circuit diagram of a semiconductor integrated circuit 100R according to comparative technique 1. A resistive voltage divider circuit 110R includes “n” (=16) poly resistors R1 to R16 connected in series. The “n” poly resistors R1 to R16 have the same size, and hence have an equivalent design value of the resistance value. The poly resistors are denoted as a first poly resistor, a second poly resistor, . . . in an order starting from a side closer to the ground node 116, and an i-th poly resistor is denoted as an Ri poly resistor.

“m” poly resistors R1 to Rm on a lower electric potential side form the lower resistor RL, and the remaining (n-m) poly resistors Rm+1 to Rn on a higher electric potential side form the upper resistor RU.

In comparative technique 1, all of the poly resistors R1 to Rn are formed on a common N-type well, and this N-type well is connected to the ground node 116.

A description is now given of influence of the voltage modulation in comparative technique 1.

A design value of a voltage division ratio in a case in which the poly resistors R1 to R16 are not influenced by the voltage modulation is m/n=1/16=0.0625 but, in practice, deviates from the design value due to the influence of the voltage modulation.

For the sake of simplicity, it is assumed that the input voltage VIN is 16 V, the design value of each of the poly resistors R is 100 kΩ, and the gradient of the voltage modulation is 1,000 ppm/V.

A midpoint voltage between the first port P1 and the second port P2 of the i-th poly resistor Ri is denoted as Vci. The voltage modulation changes according to a differential voltage (referred to as a voltage-to-well) ΔV=Vwi−Vci between the midpoint voltage Vci and a well voltage Vwi of the third port P3. In comparative technique 1, the well voltage Vwi is 0 V in all of the poly resistors Ri, and hence, ΔV is −Vci.

An actual resistance value Rri of each poly resistor Ri influenced by the voltage modulation is given as follows with respect to a design value Rd.

Rri=Rd×(1+1,000 ppm/V×ΔV)

=Rd×(1−1,000 ppm/V×Vci)

In comparative technique 1, a resistance value in consideration of the voltage modulation of each poly resistor is calculated as follows.

Vc16=15.5 V, R16=98.45 kΩ

Vc15=14.5 V, R15=98.55 kΩ

Vc14=13.5 V, R14=98.65 kΩ

Vc13=12.5 V, R13=98.75 kΩ

Vc12=11.5 V, R12=98.85 kΩ

Vc11=10.5 V, R11=98.95 kΩ

Vc10=9.5 V, R10=99.05 kΩ

Vc9=8.5 V, R9=99.15 kΩ

Vc8=7.5 V, R8=99.25 kΩ

Vc7=6.5 V, R7=99.35 kΩ

Vc6=5.5 V, R6=99.45 kΩ

Vc5=4.5 V, R5=99.55 kΩ

Vc4=3.5 V, R4=99.65 kΩ

Vc3=2.5 V, R3=99.75 kΩ

Vc2=1.5 V, R2=99.85 kΩ

Vc1=0.5 V, R1=99.95 kΩ

Thus, an actual voltage division ratio is R1/(Σ_{i=1 to n} Ri)=0.06297253, and is higher than 0.0625, which is the design value, and hence, the output voltage VOUT is 1.00756, which is higher than a design value of 1 V.

### (Comparative Technique 2)

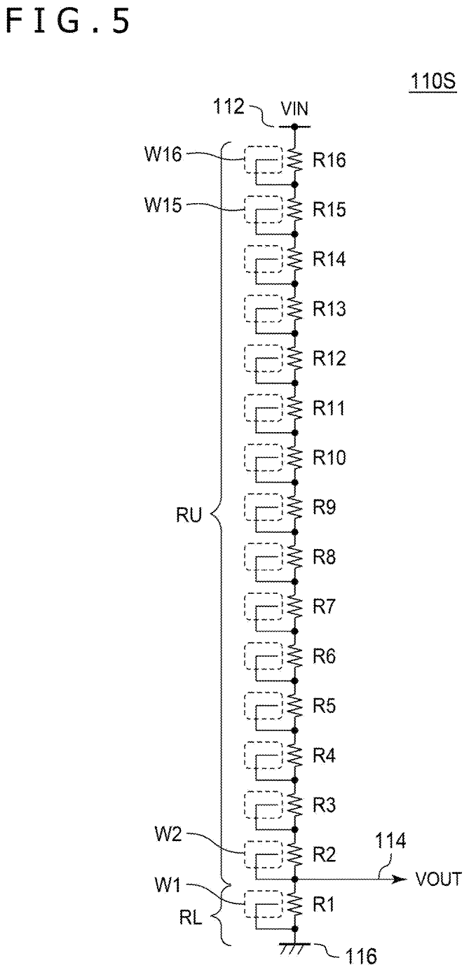

FIG. 5 is a circuit diagram of a semiconductor integrated circuit 100S according to comparative technique 2. In comparative technique 2, each of all of the poly resistors R1 to Rn is formed on each of independent N-type wells W1 to Wn, and the second port and the third port of each of the poly resistors R are connected to each other.

In comparative technique 2, the voltage-to-well ΔV is 0.5 V in all of the poly resistors R1 to R16, the same influence of the voltage modulation is applied, and hence, the resistance values of the poly resistors R1 to R16 are equivalently 99.95 kΩ. Thus, the resistance voltage division ratio is equal to the design value.

However, in comparative technique 2, the independent N-type well is required for each of the poly resistors. A separation distance defined by a design rule is required between N-type wells adjacent to each other. The separation distance is typically 10 μm. When the 16 poly resistors are arranged in one row, 15 spacings are required, and hence, 15×10 μm=150 μm becomes a useless space, and the circuit area is increased.

A description is now given of the resistive voltage divider circuit 110 according to the embodiments.

### First Embodiment

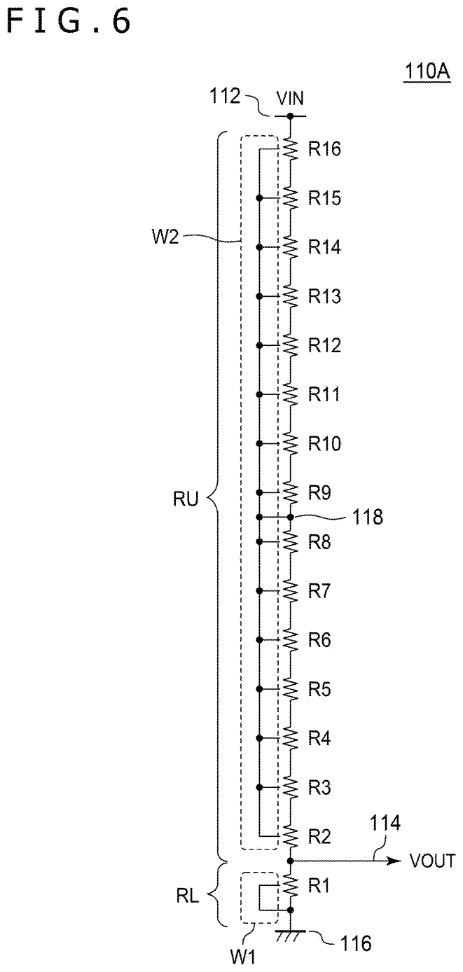

FIG. 6 is a circuit diagram of a resistive voltage divider circuit 110A according to a first embodiment. The resistive voltage divider circuit 110A includes the “n” (n≥3) poly resistors R1 to Rn having an equivalent size, in other words, having an equivalent design value of the resistance value. In this example, “n” is 16.

The output node 114 is connected to a connection node between an m-th poly resistor Rm and an (m+1)-th poly resistor Rm+1. In this example, “m” is 1.

The first to m-th poly resistors R1 to Rm (in this case, R1) form the lower resistor RL, and are formed on a first well W1. The first well W1 is connected to the ground node 116.

The upper resistor RU formed of (m+1)-th to n-th poly resistors Rm+1 to Rn (in this example, R2 to R16) is formed on a second well W2. The second well W2 is connected to a node closest to the center of the “n” poly resistors R1 to R16. In this example, the center of the poly resistors R1 to R16 is a connection node between the eighth poly resistor R8 and the ninth poly resistor R9.

There has been described a configuration of the resistive voltage divider circuit 110A according to the first embodiment. There is now examined a voltage division ratio thereof.

As in comparative technique 1, it is assumed that the input voltage VIN is 16 V, the design value of each of the poly resistors R is 100 kΩ, and the gradient of the voltage modulation is 1,000 ppm/V.

In the first embodiment, a voltage (well voltage) Vw1 of the first well W1 is 0 V, and a well voltage Vw2 of the second well W2 is 8 V.

The midpoint voltage Vc, the voltage-to-well ΔV, and a resistance value in consideration of the voltage modulation of each of the poly resistors are as described below.

Vc16=15.5 V, ΔV16=−7.5 V, R16=99.25 kΩ

Vc15=14.5 V, ΔV15=−6.5 V, R15=99.35 kΩ

Vc14=13.5 V, ΔV14=−5.5 V, R14=99.45 kΩ

Vc13=12.5 V, ΔV13=−4.5 V, R13=99.55 kΩ

Vc12=11.5 V, ΔV12=−3.5 V, R12=99.65 kΩ

Vc11=10.5 V, ΔV11=−2.5 V, R11=99.75 kΩ

Vc10=9.5 V, ΔV10=−1.5 V, R10=99.85 kΩ

Vc9=8.5 V, ΔV9=−0.5 V, R9=99.95 kΩ

Vc8=7.5 V, ΔV8=+0.5 V, R8=100.05 kΩ

Vc7=6.5 V, ΔV7=+1.5 V, R7=100.15 kΩ

Vc6=5.5 V, ΔV6=+2.5 V, R6=100.25 kΩ

Vc5=4.5 V, ΔV5=+3.5 V, R5=100.35 kΩ

Vc4=3.5 V, ΔV4=+4.5 V, R4=100.45 kΩ

Vc3=2.5 V, ΔV3=+5.5 V, R3=100.55 kΩ

Vc2=1.5 V, ΔV2=+6.5 V, R2=100.65 kΩ

Vc1=0.5 V, ΔV1=−0.5 V, R1=99.95 kΩ

Line-symmetrical voltage modulation with respect to the node connected to the second well is applied to resistance values of the (m+1)-th to n-th poly resistors R2 to R16. That is, pieces of voltage modulation opposite to each other are applied to each of a pair of R8 and R9, a pair of R7 and R10, a pair of R6 and R11, a pair of R5 and R12, a pair of R4 and R13, a pair of R3 and R14, and a pair of R2 and R15. Variations in the resistance values of the poly resistors that are present at symmetrical positions cancel each other out, and hence, the resistance value of the upper resistor Ru formed of the (m+1)-th to n-th poly resistors is hardly influenced by the voltage modulation.

A voltage division ratio of the resistive voltage divider circuit 110A is R1/(Σ_{i=1 to n} Ri)=0.0625, and hence completely matches the design value.

Moreover, the number of wells is 2, the number of spacings between the wells is 1, and hence, it is possible to outstandingly reduce the circuit area compared with comparative technique 2.

### (Modification Example 1)

A description is now given of a modification example of the resistive voltage divider circuit 110A.

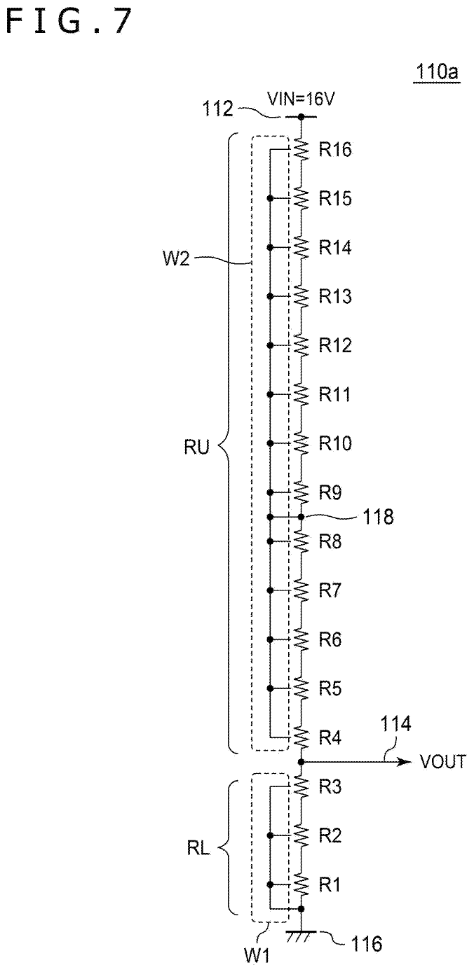

FIG. 7 is a circuit diagram of a resistive voltage divider circuit 110a according to modification example 1. In this modification example, “n” is 16, “m” is 3, and the design value of the voltage division ratio of the resistive voltage divider circuit 110a is 3/16=0.1875.

The output node 114 is connected to the connection node between the m-th poly resistor Rm and the (m+1)-th poly resistor Rm+1. In this example, “m” is 3, and hence, a connection node between the poly resistor R3 and the poly resistor R4 serves as the output node 114.

The first to m-th poly resistors R1 to Rm (in this case, R1 to R3) form the lower resistor RL, and are formed on the first well W1. The first well W1 is connected to the ground node 116.

The upper resistor RU formed of the (m+1)-th to n-th poly resistors Rm+1 to Rn (in this example, R4 to R16) is formed on the second well W2. The second well W2 is connected to the node closest to the center of the “n” poly resistors R1 to R16. In this example, the center of the poly resistors R1 to R16 is the connection node between the eighth poly resistor R8 and the ninth poly resistor R9.

Also in modification example 1, the voltage (well voltage) Vw1 of the first well W1 is 0 V, and the well voltage Vw2 of the second well W2 is 8 V.

The midpoint voltage Vc, the voltage-to-well ΔV, and a resistance value in consideration of the voltage modulation of each of the poly resistors are as described below.

Vc16=15.5 V, ΔV16=−7.5 V, R16=99.25 kΩ

Vc15=14.5 V, ΔV15=−6.5 V, R15=99.35 kΩ

Vc14=13.5 V, ΔV14=−5.5 V, R14=99.45 kΩ

Vc13=12.5 V, ΔV13=−4.5 V, R13=99.55 kΩ

Vc12=11.5 V, ΔV12=−3.5 V, R12=99.65 kΩ

Vc11=10.5 V, ΔV11=−2.5 V, R11=99.75 kΩ

Vc10=9.5 V, ΔV10=−1.5 V, R10=99.85 kΩ

Vc9=8.5 V, ΔV9=−0.5 V, R9=99.95 kΩ

Vc8=7.5 V, ΔV8=+0.5 V, R8=100.05 kΩ

Vc7=6.5 V, ΔV7=+1.5 V, R7=100.15 kΩ

Vc6=5.5 V, ΔV6=+2.5 V, R6=100.25 kΩ

Vc5=4.5 V, ΔV5=+3.5 V, R5=100.35 kΩ

Vc4=3.5 V, ΔV4=+4.5 V, R4=100.45 kΩ

Vc3=2.5 V, ΔV3=−2.5 V, R3=99.75 kΩ

Vc2=1.5 V, ΔV2=−1.5 V, R2=99.85 kΩ

Vc1=0.5 V, ΔV1=−0.5 V, R1=99.95 kΩ

A voltage division ratio of the resistive voltage divider circuit 110a is (Σ_{j=1 to m} Rj)/(Σ_{i=1 to n} Ri)=0.01875, and hence completely matches the design value.

### Second Embodiment

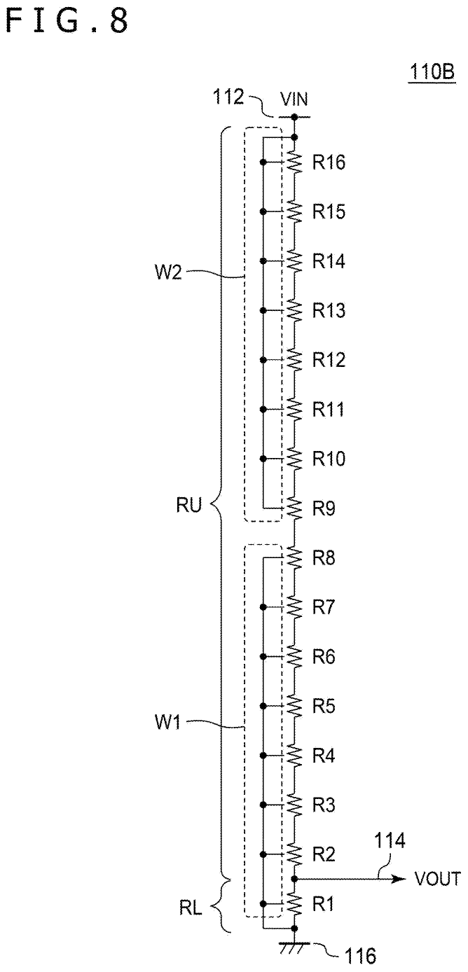

FIG. 8 is a circuit diagram of a resistive voltage divider circuit 110B according to a second embodiment. The resistive voltage divider circuit 110B includes the “n” (n≥3) poly resistors R1 to Rn having an equivalent size, in other words, having an equivalent design value of the resistance value. In this example, “n” is 16.

The output node 114 is connected to the connection node between the m-th poly resistor Rm and the (m+1)-th poly resistor Rm+1. In this example, “m” is 1.

The first to m-th poly resistors R1 to Rm (in this case, R1) form the lower resistor RL, and the (m+1)-th to n-th poly resistors Rm+1 to Rn (in this case, R2 to R16) form the upper resistor RU. “k” is an integer closest to n/2. In the case in which “n” is 16, “k” is 8. The first to k-th (in this example, “k” is 8) poly resistors R1 to R8 are formed on the first well W1, and the first well W1 is connected to the ground node 116.

The (k+1)-th to n-th poly resistors R9 to R16 are formed on the second well W2. The second well W2 is connected to the input node 112.

The voltage (well voltage) Vw1 of the first well W1 is 0 V, and the well voltage Vw2 of the second well W2 is VIN=16 V.

The midpoint voltage Vc, the voltage-to-well ΔV, and the resistance value in consideration of the voltage modulation of each of the poly resistors are as described below.

Vc16=15.5 V, ΔV16=0.5 V, R16=100.05 kΩ

Vc15=14.5 V, ΔV15=1.5 V, R15=100.15 kΩ

Vc14=13.5 V, ΔV14=2.5 V, R14=100.25 kΩ

Vc13=12.5 V, ΔV13=3.5 V, R13=100.35 kΩ

Vc12=11.5 V, ΔV12=4.5 V, R12=100.45 kΩ

Vc11=10.5 V, ΔV11=5.5 V, R11=100.55 kΩ

Vc10=9.5 V, ΔV10=6.5 V, R10=100.65 kΩ

Vc9=8.5 V, ΔV9=7.5 V, R9=100.75 kΩ

Vc8=7.5 V, ΔV8=- 7.5 V, R8=99.25 kΩ

Vc7=6.5 V, ΔV7=−6.5 V, R7=99.35 kΩ

Vc6=5.5 V, ΔV6=−5.5 V, R6=99.45 kΩ

Vc5=4.5 V, ΔV5=−4.5 V, R5=99.55 kΩ

Vc4=3.5 V, ΔV4=−3.5 V, R4=99.65 kΩ

Vc3=2.5 V, ΔV3=−2.5 V, R3=99.75 kΩ

Vc2=1.5 V, ΔV2=−1.5 V, R2=99.85 kΩ

Vc1=0.5 V, ΔV1=−0.5 V, R1=99.95 kΩ

In the second embodiment, the voltage modulation applied to the poly resistors R1 to Rk formed on the first well W1 and the voltage modulation applied to the poly resistors Rk+1 to Rn formed on the second well W2 are opposite to each other in direction, and hence, variations in the resistance values of the poly resistors formed on the first well W1 and variations in the resistance values of the poly resistors formed on the second well W2 cancel each other out.

A voltage division ratio of the resistive voltage divider circuit 110B is (Σ_{j=1 to m} Rj)/(Σ_{i=1 to n} Ri)=0.062468765, and hence, the value close to the design value of 0.0625 can be obtained.

Moreover, as described in comparative technique 2, when each of the poly resistors is formed on the independent well, the space is required between the wells, and hence, the circuit area is increased. However, with the configuration described above, the number of wells is two, the number of spaces between the wells is one, and hence, the circuit area can be reduced.

The resistive voltage divider circuit 110B according to the second embodiment has the following advantage compared with the resistive voltage divider circuit 110A according to the first embodiment.

In the first embodiment, the second well W2 is connected to a node 118 which has high impedance, in other words, which is likely to be influenced by noise. Accordingly, the noise is likely to be superimposed on the output voltage VOUT. Meanwhile, in the second embodiment, the second well W2 is connected to the input node 112. The input node 112 is connected to an output node of an unillustrated voltage source, and hence, output impedance of the voltage source is low. That is, the second well W2 is connected to the node having the low impedance. Accordingly, there is provided such a configuration that the noise is unlikely to be superimposed on the output voltage VOUT.

### (Modification Example 2)

A description is now given of a modification example of the resistive voltage divider circuit 110B.

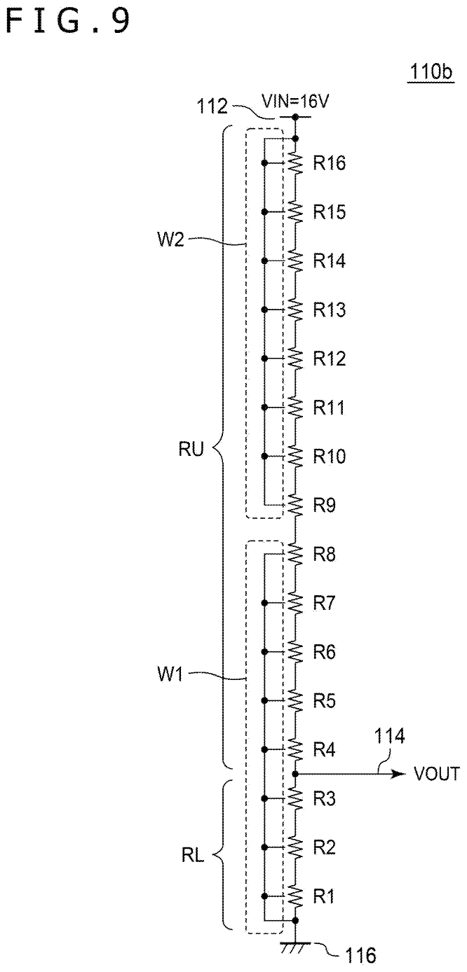

FIG. 9 is a circuit diagram of a resistive voltage divider circuit 110b according to modification example 2. In this modification example, “n” is 16, “m” is 3, and the design value of the voltage division ratio of the resistive voltage divider circuit 110b is 3/16=0.1875.

The output node 114 is connected to the connection node between the m-th poly resistor Rm and the (m+1)-th poly resistor Rm+1. In this example, “m” is 3, and hence, the connection node between the poly resistor R3 and the poly resistor R4 serves as the output node 114.

As in the second embodiment, the first to k-th poly resistors R1 to Rk (in this case, R1 to R8) are formed on the first well W1. The first well W1 is connected to the ground node 116. The voltage (well voltage) Vw1 of the first well W1 is 0 V.

As in the second embodiment, the (k+1)-th to n-th poly resistors Rk+1 to Rn (in this case, R9 to R16) are formed on the second well W2. The second well W2 is connected to the input node 112. The well voltage Vw2 of the second well W2 is 16 V.

The midpoint voltage Vc, the voltage-to-well ΔV, and the resistance value in consideration of the voltage modulation of each of the poly resistors are as described below.

Vc16=15.5 V, ΔV16 =0.5 V, R16=100.05 kΩ

Vc15=14.5 V, ΔV15=1.5 V, R15=100.15 kΩ

Vc14=13.5 V, ΔV14=2.5 V, R14=100.25 kΩ

Vc13=12.5 V, ΔV13=3.5 V, R13=100.35 kΩ

Vc12=11.5 V, ΔV12=4.5 V, R12=100.45 kΩ

Vc11=10.5 V, ΔV11=5.5 V, R11=100.55 kΩ

Vc10=9.5 V, ΔV10=6.5 V, R10=100.65 kΩ

Vc9=8.5 V, ΔV9=7.5 V, R9=100.75 kΩ

Vc8=7.5 V, ΔV8=- 7.5 V, R8=99.25 kΩ

Vc7=6.5 V, ΔV7=- 6.5 V, R7=99.35 kΩ

Vc6=5.5 V, ΔV6=- 5.5 V, R6=99.45 kΩ

Vc5=4.5 V, ΔV5=- 4.5 V, R5=99.55 kΩ

Vc4=3.5 V, ΔV4=- 3.5 V, R4=99.65 kΩ

Vc3=2.5 V, ΔV3=- 2.5 V, R3=99.75 kΩ

Vc2=1.5 V, ΔV2=- 1.5 V, R2=99.85 kΩ

Vc1=0.5 V, ΔV1=- 0.5 V, R1=99.95 kΩ

A voltage division ratio of the resistive voltage divider circuit 110b is (Σ_{j=1 to m} Rj)/(Σ_{i=1 to n} Ri)=0.18721875, and hence, the value close to the design value of 0.1875 can be obtained.

Moreover, as described in comparative technique 2, when each of the poly resistors is formed on the independent well, the space is required between the wells, and hence, the circuit area is increased. However, with the configuration described above, the number of wells is two, the number of spaces between the wells is one, and hence, the circuit area can be reduced.

### (Supplementary Notes)

The following techniques are disclosed in this specification.

### (Item 1)

A semiconductor integrated circuit including:
a semiconductor substrate; and
a resistive voltage divider circuit that is formed on the semiconductor substrate and divides an input voltage,
in which the resistive voltage divider circuit includes
an input node that receives the input voltage,
a ground node,
an output node, and
“n” (n≥3) poly resistors that are connected in series between the input node and the ground node and have the same size,
one of the “n” poly resistors closest to the ground node is referred to as a first poly resistor, and one of the “n” poly resistors closest to the input node is referred to as an n-th poly resistor,
the output node is connected to a connection node between an m-th poly resistor and an (m+1)-th poly resistor,
the first to m-th poly resistors are formed on a first well, and the first well is connected to the ground node, and
the (m+1)-th to n-th poly resistors are formed on a second well, and the second well is connected to a node closest to a center of the “n” poly resistors.

### (Item 2)

A semiconductor integrated circuit including:
a semiconductor substrate; and
a resistive voltage divider circuit that is formed on the semiconductor substrate and divides an input voltage,
in which the resistive voltage divider circuit includes
an input node that receives the input voltage,
a ground node,
an output node, and
“n” (n≥3) poly resistors that are connected in series between the input node and the ground node and have the same size,
one of the “n” poly resistors closest to the ground node is referred to as a first poly resistor, and one of the “n” poly resistors closest to the input node is referred to as an n-th poly resistor,
the output node is connected to a connection node between an m-th poly resistor and an (m+1)-th poly resistor,
when “k” is an integer closest to n/2,
the first poly resistor to a k-th poly resistor are formed on a first well, and the first well is connected to the ground node, and
a (k+1)-th poly resistor to the n-th poly resistor are formed on a second well, and the second well is connected to the input node.

### (Item 3)

The semiconductor integrated circuit according to Item 1 or 2, in which m/n is ⅛ or smaller.

### (Item 4)

The semiconductor integrated circuit according to any one of Items 1 to 3, in which “m” is 1.

The present disclosure contains subject matter related to that disclosed in Japanese Priority Patent Application JP 2025-061367 filed in the Japan Patent Office on Apr. 2, 2025, the entire content of which is hereby incorporated by reference.

What is claimed is:

1. A semiconductor integrated circuit comprising:
a semiconductor substrate; and
a resistive voltage divider circuit that is formed on the semiconductor substrate and divides an input voltage,
wherein the resistive voltage divider circuit includes
an input node that receives the input voltage,
a ground node,
an output node, and
“n” (n≥3) poly resistors that are connected in series between the input node and the ground node and have a same size,
one of the “n” poly resistors closest to the ground node is referred to as a first poly resistor, and one of the “n” poly resistors closest to the input node is referred to as an n-th poly resistor,
the output node is connected to a connection node between an m-th poly resistor and an (m+1)-th poly resistor,
the first to m-th poly resistors are formed on a first well, and the first well is connected to the ground node, and
the (m+1)-th to n-th poly resistors are formed on a second well, and the second well is connected to a node closest to a center of the “n” poly resistors.

2. A semiconductor integrated circuit comprising:
a semiconductor substrate; and
a resistive voltage divider circuit that is formed on the semiconductor substrate and divides an input voltage,
wherein the resistive voltage divider circuit includes
an input node that receives the input voltage,
a ground node,
an output node, and
“n” (n≥3) poly resistors that are connected in series between the input node and the ground node and have a same size,
one of the “n” poly resistors closest to the ground node is referred to as a first poly resistor, and one of the “n” poly resistors closest to the input node is referred to as an n-th poly resistor,
the output node is connected to a connection node between an m-th poly resistor and an (m+1)-th poly resistor,
when “k” is an integer closest to n/2,
the first poly resistor to a k-th poly resistor are formed on a first well, and the first well is connected to the ground node, and
a (k+1)-th poly resistor to the n-th poly resistor are formed on a second well, and the second well is connected to the input node.

3. The semiconductor integrated circuit according to claim 1, wherein m/n is ⅛ or smaller.

4. The semiconductor integrated circuit according to claim 2, wherein m/n is ⅛ or smaller.

5. The semiconductor integrated circuit according to claim 1, wherein “m” is 1.

6. The semiconductor integrated circuit according to claim 2, wherein “m” is 1.
